(19) United States
(12) Patent Application Publication
(10) Pub. No.: US 2019/0389771 A1
(43) Pub. Date: Dec. 26, 2019

(54) SEMICONDUCTIVE CERAMIC MEMBER AND HOLDER FOR WAFER CONVEYANCE

(71) Applicant: KYOCERA Corporation, Kyoto-shi, Kyoto (JP)

(72) Inventors: Yasuharu TATEYAMA, Kirishima-shi (JP); Shoji KOHSAKA, Kirishima-shi (JP)

(73) Assignee: KYOCERA Corporation, Kyoto-shi, Kyoto (JP)

(21) Appl. No.: 16/481,762

(22) PCT Filed: Jan. 30, 2018
(86) PCT No.: PCT/JP2018/002963

§ 371 Date: Jul. 29, 2019

(30) Foreign Application Priority Data
Jan. 30, 2017 (JP) 2017-014393
May 29, 2017 (JP) 2017-105689

(51) Int. Cl. C04B 35/117; C04B 35/626; C04B 35/634; C04B 35/645; H01L 21/673; H01L 21/677

(52) U.S. Cl. CPC C04B 35/117; B25J 15/00; C04B 35/63488; C04B 35/63416; C04B 35/63424; C04B 35/62655; C04B 35/62695; C04B 35/6455; H01L 21/673; H01L 21/677; C04B 2235/3217; C04B 2235/3234; C04B 2235/3208; C04B 2235/3229; C04B 2235/3418; C04B 2235/5436; C04B 2235/606; C04B 2235/6567; C04B 2235/77; C04B 2235/9661; C04B 35/6261

(57) ABSTRACT

A semiconductive ceramic member includes alumina ceramics containing α-alumina and titanium oxide. The alumina ceramics contains a content of 89-95% by mass of Al in terms of Al₂O₃, and a content of 5-11% by mass of Ti in terms of TiO₂. When a total content of Al in terms of Al₂O₃ and Ti in terms of TiO₂ is taken as 100 parts by mass, the alumina ceramics contains a content of 0.02-0.6 part by mass in total of Ca in terms of CaO and Ce in terms of CeO₂ relative to the 100 parts by mass. The member has a bulk density of 3.7 g/cm³ or more and a peak of TiOₓ (0<x<2) within a binding energy range of 456-462 eV in X-ray photoelectron spectroscopy. A surface of the member has a lightness index L* of 40 to 60, and ΔL* of 1 or less.

### CROSS-REFERENCE TO RELATED APPLICATIONS

This application is a national stage entry according to U.S.C. 371 of International Application No. PCT/JP2018/002963 filed on Jan. 30, 2018, which claims priority to Japanese Patent Application Nos. 2017-014393 filed on Jan. 30, 2017, 2017-105689 filed on May 29, 2017, the contents of which are entirely incorporated herein by reference.

### TECHNICAL FIELD

The present disclosure relates to a semiconductive ceramic member and a holder for wafer conveyance.

### BACKGROUND

A holder for wafer conveyance is used for holding and conveyance of a wafer in exposure equipment, etc. For the holder for wafer conveyance, there is used ceramics that exhibits high mechanical strength, and in addition, exhibits low electrical resistance to attain the capability of dissipation of static electricity for prevention of electrostatic adhesion of dust and airborne particulate matter to a wafer.

Examples of ceramics of this type include alumina ceramics which is predominantly composed of alumina (Al₂O₃) and contains titanium oxide (TiO₂). Such alumina ceramics becomes electrically conductive when fired in a reducing atmosphere.

For example, Japanese Unexamined Patent Publication JP-A 2007-91488 (Patent Literature 1) discloses alumina ceramics obtained by adding 1.0 to 2.5% by weight of ZrO₂ partially stabilized by Y₂O₃ to alumina ceramics which is predominantly composed of alumina and contains 2.5 to 7.5% by weight of TiO₂, and thereafter sintering the ZrO₂-added alumina ceramics in an reducing atmosphere. The alumina ceramics disclosed in Japanese Unexamined Patent Publication JP-A 2007-91488 (Patent Literature 1) is blackish alumina ceramics which is uniform in color, both inside and out.

### SUMMARY

A semiconductive ceramic member according to the disclosure includes alumina ceramics containing α-alumina and titanium oxide. The alumina ceramics contains a content of 89 to 95% by mass of Al in terms of Al₂O₃, and a content of 5 to 11% by mass of Ti in terms of TiO₂. In addition, when a total content of Al in terms of Al₂O₃ and Ti in terms of TiO₂ is taken as 100 parts by mass, the alumina ceramics contains a content of 0.02 to 0.6 part by mass in total of Ca in terms of CaO and Ce in terms of CeO₂ relative to the 100 parts by mass. Moreover, the semiconductive ceramic member has a bulk density of 3.7 g/cm³ or more. Further, the semiconductor ceramic member has a peak of TiOₓ (0<x<2) within a binding energy range of 456 eV to 462 eV in X-ray photoelectron spectroscopy. Furthermore, a surface of the semiconductive ceramic member has a lightness index L* of 40 or more and 60 or less, and ΔL* of 1 or less.

### BRIEF DESCRIPTION OF DRAWINGS

FIG. 1 is a view showing an example of X-ray photoelectron spectroscopy (XPS) chart for the semiconductive ceramic member according to the disclosure;

FIG. 2 is a view showing another example of X-ray photoelectron spectroscopy (XPS) chart for the semiconductive ceramic member according to the disclosure; and

FIG. 3 is a view showing still another example of X-ray photoelectron spectroscopy (XPS) chart for the semiconductive ceramic member according to the disclosure.

### DETAILED DESCRIPTION

A holder for wafer conveyance is normally required to last for many years of service with high reliability. Thus, under rigorous exterior quality standards imposed on it in connection with problems such as cracking and pinhole formation, the holder for wafer conveyance is tested for appearance to check the fulfillment of the standards. At this time, when alumina ceramics in use has a blackish dark color, or contrariwise has a whitish light color, it is difficult to visually identify cracks, as well as pinholes, in appearance testing, causing a failure in detection of cracks and pinholes.

The holder for wafer conveyance is also required to meet strict specifications about dimensions and surface properties. It is thus customary to subject a sintered compact obtained through a firing step to polishing, grinding, or other machining process. At this time, the occurrence of variation in surface color tone due to the machining process such as polishing or grinding makes it difficult to visually identify cracks and pinholes in appearance testing.

Thus, in present day holders for wafer conveyance, in addition to high mechanical strength and low electrical resistance, easiness in visual identification of cracks and pinholes in appearance testing will be needed.

A semiconductive ceramic member according to the disclosure exhibits high mechanical strength and low electrical resistance, and in addition, allows easy visual identification of cracks and pinholes when tested for appearance. The following details the semiconductive ceramic member according to the disclosure with reference to drawings.

The semiconductive ceramic member according to the disclosure is made of alumina ceramics containing α-alumina (α-Al₂O₃) and titanium oxide (TiOₓ). This alumina ceramics contains a content of 89 to 95% by mass of Al (aluminum) in terms of Al₂O₃, and a content of 5 to 11% by mass of Ti (titanium) in terms of TiO₂. When a total content of Al in terms of Al₂O₃ and Ti in terms of TiO₂ is taken as 100 parts by mass, the alumina ceramics contains a content of 0.02 to 0.6 part by mass in total of Ca (calcium) in terms of CaO and Ce (cerium) in terms of CeO₂ respective to the 100 parts by mass. The semiconductive ceramic member according to the disclosure may either contain at least one of Ca and Ce or contain both of Ca and Ce.

Moreover, the semiconductive ceramic member according to the disclosure has a bulk density of 3.7 g/cm³ or more. The bulk density is determined by calculating the bulk density of a sample cut from the semiconductive ceramic member in conformance with JIS R 1634-1998 by Archimedes' law. The bulk density may be 4.1 g/cm³ or less.

Moreover, the semiconductive ceramic member according to the disclosure has a peak of TiOₓ (0<x<2) within a binding energy range of 456 eV to 462 eV in X-ray Photoelectron Spectroscopy (XPS). As used herein TiOₓ (0<x<2) refers to TiO₂ in an oxygen-vacant state. There may be a case where, due to the presence of some oxygen vacancy-free TiO₂, TiOₓ (0<x<2) and TiO₂ coexist. In this case, the peak of TiO₂ appears within the binding energy range of 456 eV to 462 eV, whereas the peak of TiOₓ (0<x<2) appears at a binding energy higher than the binding energy at which the peak of TiO₂ is observed.

The peak of TiOₓ (0<x<2) with in the binding energy range of 456 eV to 462 eV refers to a peak of the binding energy (Ti2_{P3/2}) of a total angular momentum 3/2 of an inner orbit 2P of Ti in TiOₓ (0<x<2). The same is true for the peak of TiO₂ within the binding energy range of 456 eV to 462 eV.

Moreover, the semiconductive ceramic member according to the disclosure has a surface which exhibits ΔL* of 1 or less. The ΔL* of the surface refers to the difference between the maximum and the minimum of lightness values obtained by measuring ten or more locations on a surface part having an area of 100 cm² in diffuse reflection measurement on the basis of the lightness index L*according to the CIE 1976 L*a*b* color space. For example, the measurement is conducted with a spectrophotometric colorimeter CM-3700A manufactured by Konica Minolta, Inc. under conditions that CIE (Commission Internationale de l'Eclairage) standard illuminant D65 is used as a reference illuminant; the range of wavelengths extends from 360 nm to 740 nm; and the measurement location measures 3 mm by 5 mm.

The semiconductive ceramic member according to the disclosure, being configured to fulfill the above-described requirements, exhibits high mechanical strength and low electrical resistance, and in addition, allows easy visual identification of cracks and pinholes when tested for appearance. The high mechanical strength means that the three-point bending strength determined by measurement in conformance with JIS R 1601 (2008) is 200 MPa or more. The low electrical resistance means that the volume resistivity determined by measurement using Three-terminal method in conformance with JIS C 2141 (1992) falls in the range of 10³ Ω·cm or more and 10¹⁰ Ω·cm or less. Moreover, the “semiconductivity” of the semiconductive ceramic member according to the disclosure means that the volume resistivity of the ceramic member falls in the range of 10³ Ω·cm or more and 10¹⁰ Ω·cm or less.

The following describes ease of visual identification of cracks and pinholes in appearance testing. In the semiconductive ceramic member according to the disclosure, the lightness index L* of the surface part having an area of 100 cm² according to the CIE 1976 L*a*b* color space determined by diffuse reflection measurement falls in the range of 40 or more and 60 or less. When a* and b* are each 0, a lightness index L* of 0 corresponds to black, and a lightness index L* of 100 corresponds to white. That is, the semiconductive ceramic member according to the disclosure having the lightness index L* in the range of 40 or more and 60 or less has a color tone between black and white. In addition to the above-described color tone, in the semiconductive ceramic member according to the disclosure, ΔL* in the surface is 1 or less. Thus, the semiconductive ceramic member according to the disclosure has a color tone between black and white, and exhibits little variation in color tone. This allows easy visual identification of cracks and pinholes in appearance testing. The above-described color tone and color variation depend on the composition of the semiconductive ceramic member.

Next, the composition of the semiconductive ceramic member will be described. the content of Al of the semiconductive ceramic member according to the disclosure is 89 to 95% by mass in terms of Al₂O₃. Where the content of Al in terms of Al₂O₃ is less than 89% by mass, the mechanical strength may be decreased. On the other hand, where the content of Al in terms of Al₂O₃ exceeds 95% by mass, the volume resistivity may exceed 10¹⁰ Ω·cm.

Moreover, the content of Ti of the semiconductive ceramic member according to the disclosure is 5 to 11% by mass in terms of TiO₂. Where the content of Ti in terms of TiO₂ is less than 5% by mass, the volume resistivity may exceed 10¹⁰ Ω·cm. On the other hand, where the content of Ti in terms of TiO₂ exceeds 11% by mass, the mechanical strength may be decreased.

When the total content of Al in terms of Al₂O₃ and Ti in terms of TiO₂ is taken as 100 parts by mass, the contents of Ca and Ce of the semiconductive ceramic member according to the disclosure is 0.02 to 0.6 part by mass in total of Ca in terms of CaO and Ce in terms of CeO₂ relative to the 100 parts by mass. Where the total content is less than 0.02 part by mass, lightness index L* may be increased due to difficulty in promoting reduction of TiO₂ to TiOₓ. On the other hand, where the total content exceeds 0.6 part by mass, the mechanical strength may be decreased.

Moreover, the content of Ca in terms of CaO of the semiconductive ceramic member according to the disclosure may be in a range of 0.02 to 0.2 part by mass relative to the total content of Al in terms of Al₂O₃ and Ti in terms of TiO₂ taken as 100 parts by mass. The fulfillment of this condition allows further reduction of ΔL* and attainment of greater mechanical strength.

Besides, the content of Ce in terms of CeO₂ of the semiconductive ceramic member according to the disclosure may be in a range of 0.05 part to 0.5 part by mass relative to the total content of Al in terms of Al₂O₃ and Ti in terms of TiO₂ taken as 100 parts by mass. The fulfillment of this condition allows further reduction of ΔL* and attainment of greater mechanical strength.

The content of each constituent element in terms of its oxide of the semiconductive ceramic member according to the disclosure is obtained by determining the content of the constituent element by measurement using an X-ray fluorescence (XRF) analyzer or an inductively coupled plasma atomic emission spectroscopy (ICP-AES) analyzer, and thereafter converting the measured element content into the content of corresponding oxide. For example, the content of Al is determined by measurement using XRF or ICP-AES, and thereafter the measured value is converted into the content of Al₂O₃.

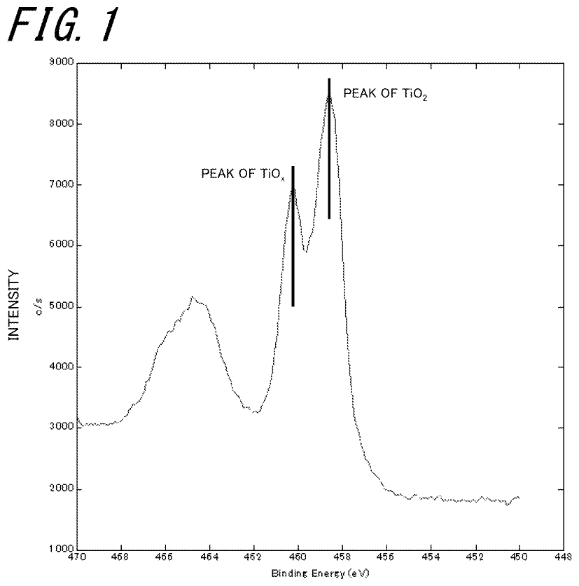

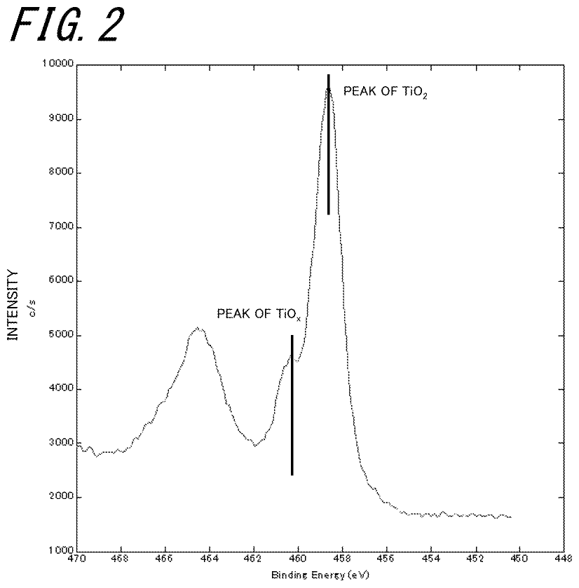

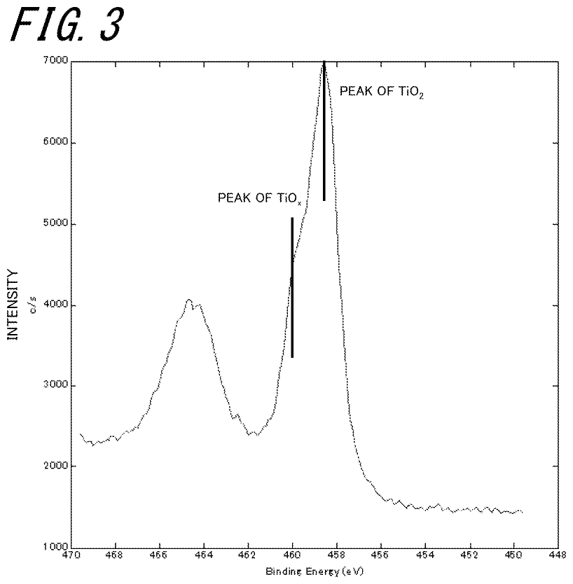

According to data obtained by XPS measurement as shown in the XPS charts of FIGS. 1 to 3, the semiconductive ceramic member according to the disclosure has the peak of TiOₓ (0<x<2) within the binding energy range of 456 eV to 462 eV. As described earlier, in the presence of the peak of TiO₂ within the binding energy range of 456 eV to 462 eV, the peak of TiOₓ(0<x<2) appears at the binding energy higher than the binding energy at which the peak of TiO₂ is observed. In FIGS. 1 to 3, the abscissa represents binding energies (eV) and the ordinate represents photoemissive intensity (c/s; counts per second). The peak of TiO₂ appears at a binding energy of about 458.6 eV, whereas the peak of TiOₓ (0<x<2) appears at a binding energy of about 459.8 eV.

Where the peak of TiOₓ (0<x<2) does not appear within the binding energy range of 456 eV to 462 eV, the volume resistivity is increased and may exceed 10¹⁰ Ω·cm. Note that the presence of the peak of TiOₓ (0<x<2) may be taken to mean not only that TiOₓ (0<x<2) exhibits a definite peak as shown in FIGS. 1 and 2, but also that TiOₓ (0<x<2) exhibits a broad peak at a binding energy higher than the binding energy at which the peak of TiO₂ is observed.

Moreover, the presence or absence of the peak of TiOₓ (0<x<2) within the binding energy range of 456 eV to 462 eV may be determined by the following measurement.

The semiconductive ceramic member according to the disclosure is subjected to measurement using, for example, X-ray photoelectron spectroscopy (XPS) equipment (PHI Quantera SXM) manufactured by ULVAC, Inc. under conditions that monochromatic AlKα radiation obtained via monochromator is used for X-ray application; X-ray output is set at 25 W; acceleration voltage is set at 15 kV; a region which is about 100 μm in diameter is measured in a single measurement operation; binding energy is counted in 0.100 eV increments; and the binding energy range for measurement extends from 448 eV to 470 eV.

Moreover, the alumina ceramic constituting the semiconductive ceramic member according to the disclosure may contain Si. A/B may be in a range of 0.3 to 1.5, wherein A represents the content of Si in terms of SiO₂ and B represents the content of Ca in terms of CaO. The fulfillment of this condition allows further reduction of ΔL*.

The content of Si in terms of SiO₂ is in a range of, for example, 0.02 to 0.15 part by mass based relative to the total content of Al in terms of Al₂O₃ and Ti in terms of TiO₂ taken as 100 parts by mass.

As described earlier, the content of Si in terms of SiO₂ is obtained by determining the content of Si by measurement using XRF or ICP-AES, and thereafter converting the measured Si content value into the content of SiO₂.

Moreover, in the semiconductive ceramic member according to the disclosure, D/(C+D) may be 0.1 or less, wherein C represents the intensity of X-ray diffraction peak for the (110) plane of titanium dioxide (TiO₂) in Miller indices notation (at 2θ of the order of about 27.4°), and D represents the intensity of X-ray diffraction peak for the (100) plane of aluminum titanate (Al₂TiO₅) in Miller indices notation (at 2θ of the order of about 26.5°). The peak intensity C refers to the peak intensity for the (110) plane of rutile titanium dioxide (TiO₂) in Miller indices notation. Moreover, CuKα radiation is used for X-ray application to the semiconductive ceramic member with X-ray diffractometer (XRD).

Rather than TiOₓ (0<x<2), titanium dioxide (TiO₂) has been evaluated for X-ray diffraction peak intensity, because JCPDS (Joint Committee on Powder Diffraction Standards) cards for TiOₓ (0<x<2) does not exist. Accordingly, that is not to say that titanium oxide is present exclusively in the form of TiO₂.

The case where D/(C+D) is 0.1 or less means that aluminum titanate having a black color, which decreases the lightness index L*, is low in abundance. Thus, where D/(C+D) is 0.1 or less, the lightness index L* is 45 or more, and ΔL* is 0.7 or less. This allows further increase in the degree of visibility of cracks and pinholes in appearance testing.

Moreover, the semiconductive ceramic member according to the disclosure may further contain trace constituents such as Na, Mg, Cr, Fe, Ni, Cu, and Y. For example, the total content of such trace constituents in terms of their oxides is in a range of 0.1% by mass or more and 0.6% by mass or less relative to the total content of all the constituents of the semiconductive ceramic member taken as 100% by mass.

Moreover, a holder for wafer conveyance according to the disclosure is formed of the semiconductive ceramic member thus structured. Forming the holder for wafer conveyance according to the disclosure from the above-described semiconductive ceramic member makes it possible to reduce the likelihood of a failure in detection of cracks and pinholes in appearance testing, and thereby afford higher reliability.

The following describes a method for manufacturing the semiconductive ceramic member and the holder for wafer conveyance according to the disclosure by way of example.

First, there are prepared α-alumina (α-Al₂O₃) powder, rutile titanium dioxide (TiO₂) powder, calcium carbonate (CaCO₃) powder, and cerium dioxide (CeO₂) powder that are of high purity, and have an average particle size of 2 μm to 5 μm, an average particle size of 1 μm to 4 μm, an average particle size of 0.7 μm to 2 μm, and an average particle size of 0.7 μm to 2 μm, respectively, by Laser diffraction and scattering technique.

Then, the α-alumina powder of 89 to 95% by mass and the rutile titanium dioxide powder of 5 to 11% by mass are weighed out. Moreover, the calcium carbonate powder and the cerium dioxide powder are weighed out so that the total content of Ca in terms of CaO and Ce in terms of CeO₂ falls in the range of 0.02 to 0.6 part by mass relative to the total content of the α-alumina powder and the rutile titanium dioxide powder taken as 100 parts by mass. After that, these powders are mixed to obtain a powder mixture.

At this time, silicon dioxide (SiO₂) powder may be added. In this case, there is prepared silicon dioxide powder which has been found to have an average particle size of 1 μm to 5 μm by laser diffraction and scattering technique, and, in the above-described process of forming the powder mixture, the silicon dioxide powder is weighed out so that A/B is in a range of 0.3 to 1.5, wherein A represents the content of Si in terms of SiO₂ and B represents the content of Ca in terms of CaO.

Next, the powder mixture, a solvent in an amount of 100 to 200 parts by mass and a dispersant in an amount of 0.02 to 0.5 part by mass relative to 100 parts by mass of the powder mixture are mixed in a ball mill, and the mixed materials are pulverized until a predetermined average particle size is reached. Then, binders such as PEG (polyethylene glycol), PVA (polyvinyl alcohol), and acrylic resin each in an amount of 4 to 10 parts by mass on a solid-content basis are added thereto, and all the materials are mixed together to obtain a slurry. Then, the slurry thus obtained is spray-dried into granules with a spray dryer.

The granules thus obtained, used as a molding raw material, are shaped into a molded body of desired shape by means of powder press molding, isostatic pressing, or otherwise, and, on an as needed basis, the molded body is subjected to cutting work. Then, the molded body is fired in the aerial atmosphere at a temperature of 1500 to 1600° C. while being retained for 2 to 12 hours to obtain a sintered compact. The sintered compact thus obtained may be subjected to grinding work on an as needed basis.

Next, in a reducing gas having a hydrogen to nitrogen ratio of 1: 3, the sintered compact thus obtained is retained at a temperature of 1300 to 1400° C. for 1 to 5 hours, and is further retained at a temperature of 1050 to 1150° C. for 1 to 30 hours. Through this reduction treatment, there is obtained the semiconductive ceramic member according to the disclosure having a bulk density of 3.7 g/cm³ or more.

By adjusting the retention time in the reduction treatment in the reducing gas having the hydrogen to nitrogen ratio of 1:3 at a temperature of 1050 to 1150° C. to 10 hours or longer, D/(C+D) can be set to 0.1 or less.

Moreover, in producing the holder for wafer conveyance according to the disclosure, in accordance with the above-described manufacturing method, the cutting work during or subsequent to the molding process and the grinding work subsequent to the firing process are performed to obtain the desired form for the holder for wafer conveyance.

Although the following specifically describes examples according to the disclosure, it will be understood that the disclosure is not limited to the following examples.

### Example 1

To begin with, there were prepared α-alumina (α-Al₂O₃) powder, rutile titanium dioxide (TiO₂) powder, calcium carbonate (CaCO₃) powder, and cerium dioxide (CeO₂) powder that were of high purity, and had an average particle size of 2 μm to 5 μm, an average particle size of 1 μm to 4 μm, an average particle size of 0.7 μm to 2 μm, and an average particle size of 0.7 μm to 2 μm, respectively, by laser diffraction and scattering technique.

Then, the individual powdery materials (the α-alumina powder, the rutile titanium dioxide powder, the calcium carbonate powder, and the cerium dioxide powder) were weighed out to obtain powder mixtures for formation of samples having different compositions as shown in Table 1.

Next, the powder mixture, a solvent in an amount of 100 parts by mass and a dispersant in an amount of 0.2 parts by mass relative to 100 parts by mass of the powder mixture were put in a ball mill for mixing, and the mixed materials were pulverized until a predetermined average particle size was reached. Then, a PEG solution in an amount of 2 parts by mass on a solid-content basis, a PVA (polyvinyl alcohol) solution in an amount of 1 part by mass on a solid-content basis, and an acrylic resin solution in an amount of 1 part by mass on a solid-content basis were added thereto, and all the materials were mixed together to obtain a slurry. The slurry thus obtained was spray-dried into granules with a spray dryer.

Then, the granules thus obtained were charged into a rubber mold, and shaped into a plurality of molded bodies, each measuring 160 mm by 160 mm by 15 mm, by isostatic pressing technique. The molded bodies were fired in the aerial atmosphere at a temperature of 1550° C. for 5 hours to obtain sintered compacts. The sintered compacts thus obtained were retained at a temperature of 1350° C. for 3 hours in a reducing gas having a hydrogen to nitrogen ratio of 1:3, and further retained at a temperature of 1100° C. for 3 hours in the reducing gas. Following the completion of this reduction treatment, only one principal surface of each sintered compact was ground by 2 mm in a thickness direction thereof. In this way, Sample Nos. 1 through 12 were obtained.

Then, a test sample was cut from each of Sample Nos. 1 through 12 for bulk density measurement. The bulk density of each test sample was calculated in conformance with JIS R 1634-1998 by Archimedes' law. The result of the calculation showed that each and every test sample has a bulk density of 3.7 g/cm³ or more.

Next, a test sample for XPS measurement was cut from each of Sample Nos. 1 through 12 so that the ground principal surface of each of Samples can serve as a measurement surface. The presence or absence of the peak of TiOₓ (0<x<2) within a binding energy range of from 456 eV to 462 eV in each test sample was determined by the XPS measurement. Similarly, the presence or absence of the peak of TiO₂ was also determined.

The XPS measurement was conducted under conditions that X-ray Photoelectron Spectroscopy (XPS) equipment (PHI Quantera SXM) manufactured by ULVAC, Inc. was used; monochromatic AlKα radiation obtained via monochromator was used for X-ray application; X-ray output was set at 25 W; acceleration voltage was set at 15 kV; a region which is about 100 μm in diameter was measured in a single measurement operation; binding energy was counted in 0.100 eV increments; and intensity (count/sec) was measured within a binding energy range of 448 eV to 470 eV.

Then, with use of spectrophotometric colorimeter CM-3700A manufactured by Konica Minolta, Inc., a region having an area of 100 cm² in the ground principal surface of each of Sample Nos. 1 through 12 serving as a measurement surface (a 10 cm-by-10 cm square region in the principal surface) was subjected to diffuse reflection measurement to determine its lightness index L* according to the CIE 1976 L*a*b* color space, as well as ΔL*. The measurement was conducted under conditions that CIE (Commission Internationale de l'Eclairage) standard illuminant D65 was used as a reference illuminant; the range of wavelengths extended from 360 nm to 740 nm; and the region subjected to a single measurement operation measured 3 mm by 5 mm. Moreover, in each of Samples, in a different measurement region, the lightness indices L* of substantially equi-spaced 16 locations were measured, and, with the mean value of all the data defined as the lightness index L*, the difference between the maximum L* and the minimum L* was defined as ΔL*.

Moreover, the mechanical strength and the volume resistivity of each of Sample Nos. 1 through 12 were measured. In mechanical strength measurement, in conformance with JIS R 1601 (2008), the three-point bending strength of a test sample cut from each of Samples was determined. In volume resistivity measurement, in conformance with JIS C 2141 (1992), the volume resistivity of a test sample cut from each of Samples was determined by Three-terminal method. Ultrahigh insulation resistance meter 8340A manufactured by ADC CORPORATION was used for the measurement.

The measurement result is shown in Table 1.

TABLE 1

| | | | | | Total | | | | | | |
|---|---|---|---|---|---|---|---|---|---|---|---|
| | | | | | of | | | | | | |
| | | | | | CaO | | | | | | |
| | | | | | and | | | | | | |
| | Al₂O₃ | TiO₂ | CaO | CeO₂ | CeO₂ | | TiOₓ | | | Bending | Volume |
| | (% by | (% by | (part by | (part by | (part by | TiO₂ | (x < 2) | | | strength | resistivity |
| No. | mass) | mass) | mass) | mass)″ | mass) | peak | peak | L* | ΔL* | (MPa) | (Ω · cm) |
| 1 | 88 | 12 | 0.05 | 0 | 0.05 | Observed | Observed | 38 | 0.9 | 188 | 1 × 10² |
| 2 | 89 | 11 | | | | Observed | Observed | 40 | 0.9 | 270 | 2 × 10³ |
| 3 | 91 | 9 | | | | Observed | Observed | 45 | 0.9 | 294 | 4 × 10⁵ |
| 4 | 93 | 7 | | | | Observed | Observed | 49 | 0.9 | 319 | 8 × 10⁶ |
| 5 | 95 | 5 | | | | Observed | Observed | 55 | 0.9 | 327 | 1 × 10⁹ |
| 6 | 96 | 4 | | | | Observed | Observed | 58 | 1.3 | 330 | 6 × 10¹¹ |
| 7 | 88 | 12 | 0 | 0.3 | 0.3 | Observed | Observed | 44 | 0.9 | 189 | 1 × 10² |
| 8 | 89 | 11 | | | | Observed | Observed | 45 | 0.9 | 280 | 2 × 10³ |
| 9 | 91 | 9 | | | | Observed | Observed | 48 | 0.9 | 303 | 2 × 10⁵ |
| 10 | 93 | 7 | | | | Observed | Observed | 50 | 0.9 | 328 | 5 × 10⁶ |
| 11 | 95 | 5 | | | | Observed | Observed | 52 | 0.9 | 336 | 8 × 10⁸ |
| 12 | 96 | 4 | | | | Observed | Observed | 55 | 1.4 | 337 | 5 × 10¹¹ |

The result of evaluation on Sample Nos. 1 through 12 showed that Sample No. 1 and Sample No. 7, each having the content of Ti in terms of TiO₂ of 12% by mass, have a three-point bending strength of 189 MPa or less, and that Sample No. 6 and Sample No. 12, each having the content of Ti in terms of TiO₂ of 4% by mass, have a volume resistivity of 5×10¹⁰ Ω·cm or more.

On the other hand, Sample Nos. 2 through 5 and Sample Nos. 8 through 11 had a volume resistivity of 2×10³ Ω·cm to 1×10⁹ Ω·cm, which indicated good semiconductivity, and a high three-point bending strength of 270 MPa to 336 MPa. Moreover, the lightness index L* was 40 to 55, and ΔL* was 1 or less.

The result of chromaticness index measurement conducted concurrently with the lightness index L* measurement showed that Sample Nos. 2 through 5 and Sample Nos. 8 through 11 had a chromaticness index a* of −4.0 to −1.5, and a chromaticness index b* of −10.0 to −7.0.

### Example 2

Sample Nos. 13 through 37 were produced basically in the same method as that used to form the samples of Example 1, except for material compositions as can be seen from Table 2. Then, bulk density measurement, XPS measurement, color tone measurement, mechanical strength measurement, and volume resistivity measurement have been performed on each sample in a manner similar to that adopted in Example 1.

The measurement result is shown in Table 2. Note that each and every sample has been found to have a bulk density of 3.7 g/cm³ or more.

TABLE 2

| | | | | | Total | | | | | | |
|---|---|---|---|---|---|---|---|---|---|---|---|
| | | | | | of | | | | | | |
| | | | | | CaO | | | | | | |
| | | | | | and | | | | | | |
| | Al₂O₃ | TiO₂ | CaO | CeO₂ | CeO₂ | | TiOₓ | | | Bending | Volume |
| | (% by | (% by | (part by | (part by | (part by | TiO₂ | (x < 2) | | | strength | resistivity |
| No. | mass) | mass) | mass) | mass)″ | mass) | peak | peak | L* | ΔL* | (MPa) | (Ω · cm) |
| 13 | 92 | 8 | 0.01 | 0 | 0.01 | Observed | Observed | 62 | 1.5 | 315 | 9 × 10⁶ |
| 14 | | | 0.02 | | 0.02 | Observed | Observed | 60 | 0.9 | 311 | 1 × 10⁶ |
| 15 | | | 0.04 | | 0.04 | Observed | Observed | 53 | 0.9 | 298 | 8 × 10⁵ |
| 16 | | | 0.07 | | 0.07 | Observed | Observed | 45 | 0.9 | 282 | 5 × 10⁵ |
| 17 | | | 0.1 | | 0.1 | Observed | Observed | 44 | 0.9 | 241 | 3 × 10⁵ |
| 18 | | | 0.12 | | 0.12 | Observed | Observed | 43 | 0.8 | 236 | 2 × 10⁵ |
| 19 | | | 0.15 | | 0.15 | Observed | Observed | 42 | 0.8 | 230 | 2 × 10⁵ |
| 20 | | | 0.2 | | 0.2 | Observed | Observed | 41 | 0.8 | 224 | 2 × 10⁵ |
| 21 | | | 0.3 | | 0.3 | Observed | Observed | 41 | 0.8 | 200 | 2 × 10⁵ |
| 22 | | | 0.7 | | 0.7 | Observed | Observed | 36 | 0.8 | 183 | 1 × 10⁵ |
| 23 | | | 0 | 0.01 | 0.01 | Observed | Observed | 62 | 1.5 | 326 | 6 × 10⁶ |
| 24 | | | | 0.03 | 0.03 | Observed | Observed | 60 | 1 | 323 | 5 × 10⁵ |
| 25 | | | | 0.05 | 0.05 | Observed | Observed | 54 | 0.9 | 323 | 4 × 10⁵ |
| 26 | | | | 0.3 | 0.3 | Observed | Observed | 49 | 0.9 | 317 | 3 × 10⁵ |
| 27 | | | | 0.5 | 0.5 | Observed | Observed | 43 | 0.9 | 273 | 3 × 10⁵ |
| 28 | | | | 0.6 | 0.6 | Observed | Observed | 42 | 0.9 | 204 | 5 × 10⁵ |
| 29 | | | | 0.7 | 0.7 | Observed | Observed | 42 | 0.9 | 185 | 7 × 10⁵ |
| 30 | | | 0.005 | 0.005 | 0.01 | Observed | Observed | 42 | 1.5 | 314 | 7 × 10⁵ |
| 31 | | | 0.01 | 0.01 | 0.02 | Observed | Observed | 55 | 1 | 312 | 5 × 10⁵ |
| 32 | | | 0.01 | 0.03 | 0.04 | Observed | Observed | 54 | 1 | 324 | 5 × 10⁵ |
| 33 | | | 0.02 | 0.05 | 0.07 | Observed | Observed | 53 | 0.9 | 318 | 8 × 10⁵ |
| 34 | | | 0.04 | 0.3 | 0.34 | Observed | Observed | 48 | 0.9 | 304 | 5 × 10⁵ |
| 35 | | | 0.1 | 0.5 | 0.6 | Observed | Observed | 41 | 0.9 | 250 | 2 × 10⁵ |
| 36 | | | 0.2 | 0.4 | 0.6 | Observed | Observed | 40 | 0.9 | 227 | 2 × 10⁵ |
| 37 | | | 0.01 | 0.55 | 0.56 | Observed | Observed | 42 | 0.9 | 206 | 9 × 10⁵ |

Sample No. 13, Sample No. 23, and Sample No. 30 have the value of ΔL* which was as large as 1.5, and that Sample No. 22 and Sample No. 29 had a three-point bending strength which was as low as 185 MPa or less.

On the other hand, Sample Nos. 14 through 21, Sample Nos. 24 through 28, and Sample Nos. 31 through 37, each having the total content of Ca in terms of CaO and Ce in terms of CeO₂ in the range of 0.02 to 0.6 part by mass, had a volume resistivity of 2×10⁵ Ω·cm to 1×10⁶ Ω·cm, which indicated good semiconductivity, and a high three-point bending strength of 200 MPa to 324 MPa. Moreover, the lightness index L* was 40 to 60, and ΔL* was 1 or less.

As can be seen from Tables 1 and 2, the measurement tests resulted in the discovery that high mechanical strength and low electrical resistance, and in addition, easiness in visual identification of cracks and pinholes in appearance testing can be achieved when fulfilling the following conditions that alumina ceramics contains α-alumina and titanium oxide; the alumina ceramics contains the content of 89 to 95% by mass of Al in terms of Al₂O₃, and the content of 5 to 11% by mass of Ti in terms of TiO₂; when the total content of Al in terms of Al₂O₃ and Ti in terms of TiO₂ is taken as 100 parts by mass, the alumina ceramics contains the content of 0.02 to 0.6 part by mass in total of Ca in terms of CaO and Ce in terms of CeO₂ relative to the 100 parts by mass; the semiconductive ceramic member has a bulk density of 3.7 g/cm³ or more; the semiconductor ceramic member has a peak of TiOₓ (0<x<2) within a binding energy range of 456 eV to 462 eV in X-ray photoelectron spectroscopy; and a surface of the semiconductive ceramic member has a lightness index L* of 40 or more and 60 or less, and ΔL* of 1 or less.

The result of chromaticness index measurement conducted concurrently with the lightness index L* measurement showed that Sample Nos. 14 through 21, Sample Nos. 24 through 28, and Sample Nos. 31 through 37 had a chromaticness index a* of −4.0 to −1.5, and a chromaticness index b* of −10.0 to −7.0.

Moreover, it was found that, of Sample Nos. 14 through 21, Sample Nos. 24 through 28, and Sample Nos. 31 through 37, particularly Sample Nos. 14 through 20, Sample Nos. 25 through 27, and Sample Nos. 33 through 36 had higher values of ΔL* which was 0.9 or less, and a three-point bending strength of 224 MPa to 323 MPa. It would thus be seen that further decrease of ΔL* and further increase of mechanical strength could be achieved when fulfilling the condition that the content of Ca in terms of CaO was 0.02 to 0.2 part by mass, or the content of Ce in terms of CeO₂ was 0.05 to 0.5 part by mass.

### Example 3

Sample Nos. 38 through 45 were produced basically in the same method as that used to form Sample No. 18 of Example 2, except that, with the preparation of silicon dioxide powder which had been found to have an average particle size of 1 μm to 5 μm by laser diffraction and scattering technique, constituent powder materials (α-alumina powder, rutile titanium dioxide powder, silicon dioxide powder, and calcium carbonate powder) were weighed out to obtain powder mixtures for formation of samples having different compositions as shown in Table 3. Sample No. 38 is identical with Sample No. 18 of Example 2.

Moreover, XRF measurement was performed on each sample to calculate A/B, wherein A represented the content of Si in terms of SiO₂ and B represented the content of Ca in terms of CaO.

Then, color tone measurement was performed on each sample in a manner similar to that adopted in Example 1.

The measurement result is shown in Table 3.

TABLE 3

| | Al₂O₃ | TiO₂ | SiO₂ | CaO | | | |
|---|---|---|---|---|---|---|---|
| | (% by | (% by | (part by | (part by | | | |
| No. | mass) | mass) | mass) | mass) | A/B | L* | ΔL* |
| 38 | 92 | 8 | 0 | 0.12 | 0.00 | 43 | 0.8 |
| 39 | | | 0.02 | 0.2 | 0.10 | 41 | 0.8 |
| 40 | | | 0.15 | 0.08 | 1.88 | 45 | 0.8 |
| 41 | | | 0.02 | 0.066 | 0.30 | 46 | 0.7 |
| 42 | | | 0.01 | 0.03 | 0.33 | 44 | 0.6 |
| 43 | | | 0.15 | 0.2 | 0.75 | 41 | 0.5 |
| 44 | | | 0.12 | 0.12 | 1.00 | 43 | 0.5 |
| 45 | | | 0.15 | 0.1 | 1.50 | 44 | 0.7 |

As shown in Table 3, Sample Nos. 41 through 45 having the value of A/B of 0.3 to 1.5 were smaller in the value of ΔL* than Sample Nos. 38 through 40. It would thus be seen that cracks and pinholes could be visually identified more easily in appearance testing when fulfilling the condition that the value of A/B was in a range of 0.3 to 1.5.

### Example 4

Sample Nos. 46 through 50 were produced basically in the same method as that used to form Sample No. 15 of Example 2, except that the time for further retention at a temperature of 1100° C. was varied as shown in Table 4.

Then, XRD measurement was performed on each sample to calculate D/(C+D), wherein C represented the X-ray diffraction peak intensity for the (110) plane of titanium dioxide in Miller indices notation, and D represented the X-ray diffraction peak intensity for the (100) plane of aluminum titanate in Miller indices notation.

In the XRD measurement, X'PertPRO manufactured by PANalytical Ltd. was used as X-ray diffractometer, and CuKα radiation was effected at diffraction angles 2θ ranging from 20° to 40°. A diffraction angle 2θ corresponding to XRD peak for the (110) plane of titanium dioxide in Miller indices notation was about 27.4°. A diffraction angle 2θ corresponding to XRD peak for the (100) plane of aluminum titanate in Miller indices notation was about 26.5°. Each X-ray diffraction peak intensity was derived from a value obtained by calculation with removal of background (background noise, etc.).

Then, color tone measurement, mechanical strength measurement, and volume resistivity measurement were performed on each sample in a manner similar to that adopted in Example 1.

The measurement result is shown in Table 4.

TABLE 4

| | Retention | | | | Bending | Volume |
|---|---|---|---|---|---|---|
| | time | D/ | | | strength | resistivity |
| No. | (hour) | (C + D) | L* | ΔL* | (MPa) | (Ω · cm) |
| 46 | 30 | 0.01 | 53 | 0.3 | 303 | 6 × 10⁵ |
| 47 | 20 | 0.02 | 52 | 0.5 | 303 | 7 × 10⁵ |
| 48 | 15 | 0.05 | 49 | 0.6 | 302 | 7 × 10⁵ |
| 49 | 10 | 0.1 | 45 | 0.7 | 302 | 8 × 10⁵ |
| 50 | 5 | 0.2 | 42 | 0.9 | 298 | 8 × 10⁵ |

As shown in Table 4, Sample Nos. 46 through 49 in which the value of D/(C+D) was 1 or less were smaller in the value of ΔL* than Sample No. 50. It would thus be seen that cracks and pinholes could be visually identified even more easily in appearance testing when fulfilling the condition that the value of D/(C+D) was 1 or less.

1. A semiconductive ceramic member, comprising:
alumina ceramics comprising α-alumina and titanium oxide, the alumina ceramics comprising a content of 89 to 95% by mass of Al in terms of Al₂O₃, and a content of 5 to 11% by mass of Ti in terms of TiO₂, when a total content of Al in terms of Al₂O₃ and Ti in terms of TiO₂ is taken as 100 parts by mass, the alumina ceramics comprising a content of 0.02 to 0.6 part by mass in total of Ca in terms of CaO and Ce in terms of CeO₂ relative to the 100 parts by mass,
the semiconductive ceramic member having a bulk density of 3.7 g/cm³ or more, the semiconductive ceramic member having a peak of TiOₓ (0<x<2) within a binding energy range of 456 eV to 462 eV in X-ray photoelectron spectroscopy measurement, a surface of the semiconductive ceramic member having a lightness index L* of 40 or more and 60 or less, and ΔL* of 1 or less.

2. The semiconductive ceramic member according to claim 1,
wherein a content of Ca in terms of CaO is in a range of 0.02 to 0.2 part by mass relative to the total content of Al in terms of Al₂O₃ and Ti in terms of TiO₂ taken as 100 parts by mass.

3. The semiconductive ceramic member according to claim 1,
wherein a content of Ce in terms of CeO₂ is in a range of 0.05 to 0.5 part by mass relative to the total content of Al in terms of Al₂O₃ and Ti in terms of TiO₂ taken as 100 parts by mass.

4. The semiconductive ceramic member according to claim 1,
wherein the alumina ceramics comprises Si, and
A/B is in a range of 0.3 to 1.5, wherein A represents a content of Si in terms of SiO₂ and B represents the content of Ca in terms CaO.

5. The semiconductive ceramic member according to claim 1,
wherein the alumina ceramics comprises aluminum titanate, and
D/(C+D) is 0.1 or less, wherein C represents X-ray diffraction peak intensity for (110) plane of titanium dioxide in Miller indices notation, and D represents X-ray diffraction peak intensity for (100) plane of the aluminum titanate in Miller indices notation.

6. A holder for wafer conveyance, comprising:
the semiconductive ceramic member according to claim 1.
